(19) United States
(12) Patent Application Publication
(10) Pub. No.: US 2026/0221088 A1
(43) Pub. Date: Jul. 30, 2026

(54) STACKED TIMING CONTROLLER AND DISPLAY APPARATUS INCLUDING THE SAME

(71) Applicant: LG Display Co., Ltd., Seoul (KR)

(72) Inventors: Hyun Taek NAM, Paju-si (KR); Un Sang YU, Paju-si (KR); Min Sung KANG, Paju-si (KR); Ki Yol CHONG, Paju-si (KR)

(73) Assignee: LG Display Co., Ltd., Seoul (KR)

(21) Appl. No.: 19/253,082

(22) Filed: Jun. 27, 2025

(30) Foreign Application Priority Data
Jan. 24, 2025 (KR) 10-2025-0011379

(51) Int. Cl. G09G 3/3225

(52) U.S. Cl. CPC G09G 3/3225; G09G 2300/0426; G09G 2310/08; G09G 2330/021

(57) ABSTRACT

A stacked timing controller includes a first control chip manufactured by a wafer process of a first circuit line width and a second control chip manufactured by a wafer process of a second circuit line width. The second circuit line width is greater than the first circuit line width, and the second control chip is vertically bonded to the first control chip. The first control chip includes at least one first logic circuit of a first design modification period, and the second control chip includes at least one second logic circuit of a second design modification period which is shorter than the first design modification period.

### CROSS-REFERENCE TO RELATED APPLICATIONS

This application claims the benefit of and priority to Korean Patent Application No. 10-2025-0011379 filed on Jan. 24, 2025, the entire contents of which are incorporated herein by reference for all purposes as if fully set forth herein.

### BACKGROUND

### 1. Technical Field

The present disclosure relates to a stacked timing controller and a display apparatus including the same.

### 2. Description of Related Art

Display apparatuses write image data in pixels included in a screen to display an image corresponding to the image data. Display apparatuses include a timing controller for controlling processing of image data and an operation of a panel driver.

The timing controller includes circuit blocks such as an analog block, a digital block, a memory block, and the like, and due to this, a chip size of the timing controller increases. As a chip size of the timing controller increases, a mount space of a printed circuit board with the timing controller mounted thereon is insufficient, and the manufacturing cost increases.

Moreover, in timing controllers, because an entire chip should be corrected even when correction on some blocks is needed, time and cost needed for design modification (or redevelopment).

The description of related art should not be considered prior art merely because it is mentioned in or associated with this section. The description of related art includes information that describes one or more aspects of the subject technology, and the description in this section does not limit the scope of the invention.

### SUMMARY

To overcome the aforementioned problems of the related art, one or more aspects of the present disclosure may provide a stacked timing controller and a display apparatus including the same, in which time and cost needed for modifying a chip size and a design may be reduced.

To achieve these aspects and other advantages and in accordance with the purpose of the disclosure, as embodied and broadly described herein, a stacked timing controller includes: a first control chip manufactured by a wafer process of a first circuit line width; and a second control chip manufactured by a wafer process of a second circuit line width, wherein the second circuit line width is greater than the first circuit line width, wherein the second control chip is vertically bonded to the first control chip, wherein the first control chip includes at least one first logic circuit of a first design modification period, and wherein the second control chip includes at least one second logic circuit of a second design modification period which is shorter than the first design modification period.

In another aspect of the present disclosure, a stacked timing controller includes: a first control chip manufactured by a wafer process of a first circuit line width; and a second control chip manufactured by a wafer process of a second circuit line width, wherein the second circuit line width is greater than the first circuit line width, wherein the second control chip is vertically bonded to the first control chip, and wherein a bus interface line for signal transfer between internal elements and a power line for transferring a driving power to the internal elements are included in a top metal layer included in at least one of the first control chip and the second control chip.

A display apparatus according to an embodiment of the present disclosure may include the stacked timing controller described above.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a diagram illustrating a schematic configuration of a stacked timing controller where control chips manufactured through different processes are bonded to each other;

FIG. 2 is a diagram illustrating the kinds of circuits embedded in a first control chip and a second control chip;

FIG. 3 is a diagram illustrating a first junction example between a first control chip and a second control chip;

FIG. 4 is a diagram illustrating a second junction example between a first control chip and a second control chip;

FIG. 5 is a diagram illustrating a third junction example between a first control chip and a second control chip;

FIG. 6 is a diagram illustrating a fourth junction example between a first control chip and a second control chip;

FIG. 7 is a diagram illustrating an example where a stacked timing controller is mounted on a package substrate;

FIG. 8 is a diagram illustrating an example where a bus interface line is formed in a top metal layer included in at least one of a first control chip and a second control chip;

FIGS. 9A and 9B are diagrams illustrating a junction example between the first control chip and the second control chip of FIG. 8;

FIGS. 10A and 10B are diagrams illustrating another junction example between the first control chip and the second control chip of FIG. 8;

FIGS. 11 and 12 are diagrams illustrating examples where a bus interface line is formed in various open loop shapes in a top metal layer included in at least one of a first control chip and a second control chip; and

FIG. 13 is a diagram illustrating a display apparatus including a stacked timing controller according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, the present disclosure will be described more fully with reference to the accompanying drawings, in which exemplary embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

The shapes, sizes, ratios, angles, numbers and the like disclosed in the drawings for description of various embodiments of the present disclosure to describe embodiments of the present disclosure are merely exemplary and the present disclosure is not limited thereto. Like reference numerals refer to like elements throughout. Throughout this specification, the same elements are denoted by the same reference numerals. As used herein, the terms “comprise”, “having”, “including” and the like suggest that other parts can be added unless the term “only” is used. As used herein, the singular forms “a”, “an”, and “the” are intended to include the plural forms as well, unless context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Elements in various embodiments of the present disclosure are to be interpreted as including margins of error even without explicit statements.

In describing a position relationship, for example, when a position relation between two parts is described as “on~”, “over~”, “under~”, and “next~”, one or more other parts may be disposed between the two parts unless “just” or “direct” is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Hereinafter, embodiments of the present disclosure will be described in detail with reference to the accompanying drawings. In descriptions below, when detailed descriptions of elements or technology relevant to the present disclosure are determined to unnecessarily obscure the gist of the present disclosure, its detailed description is omitted.

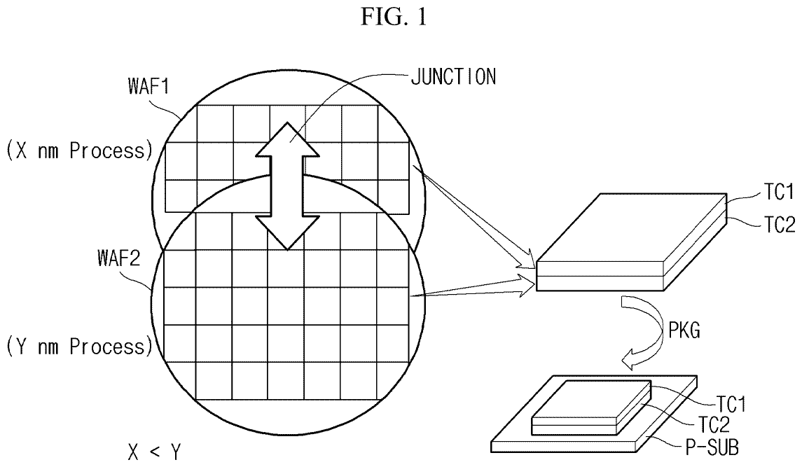

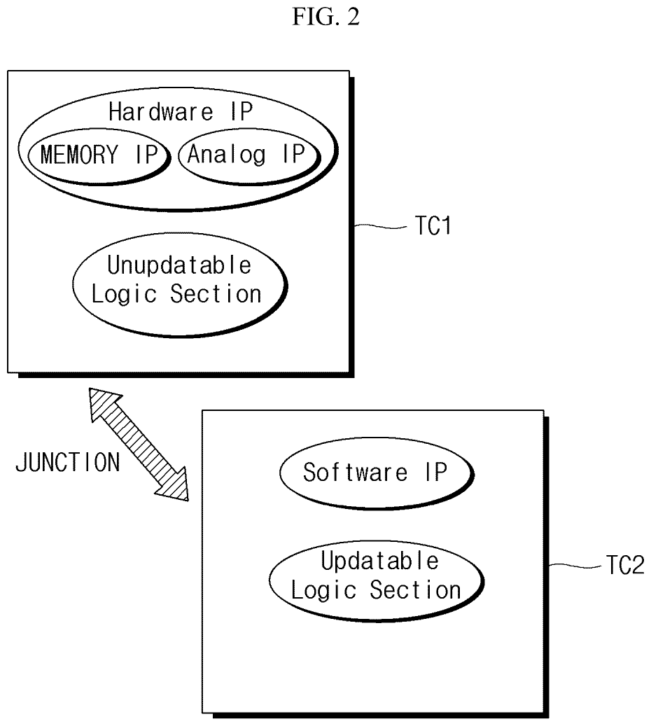

FIG. 1 is a diagram illustrating a schematic configuration of a stacked timing controller where control chips manufactured through different processes are bonded to each other. FIG. 2 is a diagram illustrating the kinds of circuits embedded in a first control chip and a second control chip.

Referring to FIGS. 1 and 2, a stacked timing controller according to an embodiment of the present disclosure may be configured based on a vertical junction between a first control chip TC1 and a second control chip TC2. The first control chip TC1 and the second control chip TC2 may be bonded to each other and may then be mounted on a package substrate P-SUB, and thus, the stacked timing controller may be finished.

The first control chip TC1 may be manufactured by a wafer process of a first circuit line width (X nm). A first wafer WAF1 including the first control chip TC1 may be manufactured through a wafer process which is relatively high in cost, and the first circuit line width (X nm) may be, for example, about 22 nm or about 16 nm.

The second control chip TC2 may be manufactured by a wafer process of a second circuit line width (Y nm) which is greater than the first circuit line width (X nm). A second wafer WAF2 including the second control chip TC2 may be manufactured through a wafer process which is relatively low in cost, and the second circuit line width (Y nm) may be, for example, about 40 nm.

The first control chip TC1 manufactured through a high-cost wafer process may include a plurality of circuit blocks requiring no design modification. At least one first logic circuit having a first design modification period may be included in the first control chip TC1. For example, the first logic circuit may include logic circuits such as an organic light emitting diode (OLED) compensation algorithm, a camera compensation algorithm, and a performance improvement algorithm, but is not limited thereto.

The first control chip TC1 may further include hardware intellectual property (IP) (for example, memory IP and analog IP). The hardware IP may be IP of a design data form where arrangement and wiring are completed based on a predetermined process, and because the hardware IP is usable in only a specific process, design modification may be difficult. However, the hardware IP may have the high stability and reliability of performance, and due to this, cost may be high.

The second control chip TC2 manufactured through a low-cost wafer process may include a plurality of circuit blocks requiring frequent design modification. At least one second logic circuit having a second design modification period which is shorter than the first design modification period may be included in the second control chip TC2. For example, the second logic circuit may include logic circuits such as an image quality compensation algorithm and a luminance compensation algorithm, but is not limited thereto.

The second control chip TC2 may further include software IP. The software IP may be at a register transfer level (RTL) capable of logic synthesis, a manufacturing process thereof may not be predetermined, and the easiness of design modification may be high, but cost may be relatively low. The software IP may include, for example, central processing unit (CPU) IP and graphics processing unit (GPU) IP.

The first control chip TC1 and the second control chip TC2 may be manufactured with the same size, and thus, a mount area of a printed circuit board (PCB) may be minimized.

Particularly, time and cost needed for design modification may be considerably reduced based on a dualization design where only circuit blocks substantially requiring no design modification are included in the first control chip TC1 which is high in cost, and circuit blocks where design modification is frequently performed based on the requirement of customer are included in the second control chip TC2. When only the second control chip TC2 is a target of design modification, only upgrading of the low-cost second control chip TC2 may be performed, and upgrading of the high-cost first control chip TC1 may not be needed, and thus, time and cost needed for design modification may be reduced in proportion thereto.

The first design modification period of the first control chip TC1 may be very long, and thus, the first control chip TC1 in the stacked timing controller may be substantially referred to as a fixed region.

The second design modification period of the second control chip TC2 may be very short, based on the requirement of customer, and thus, the second control chip TC2 in the stacked timing controller may be substantially referred to as a variable region.

When the necessity for correction occurs in the variable region, only the variable region may be corrected, and thus, time and cost needed for design modification may be considerably reduced.

Hereinafter, various junction examples between the first control chip TC1 and the second control chip TC2 will be described. In a junction configuration according to the following embodiments, because the first control chip TC1 and the second control chip TC2 have the same size, a wire connection configuration for connecting chips of different sizes with each other may not be needed, and a junction configuration may be relatively simple. Accordingly, a configuration needed for junction may be simplified, and the manufacturing cost may decrease.

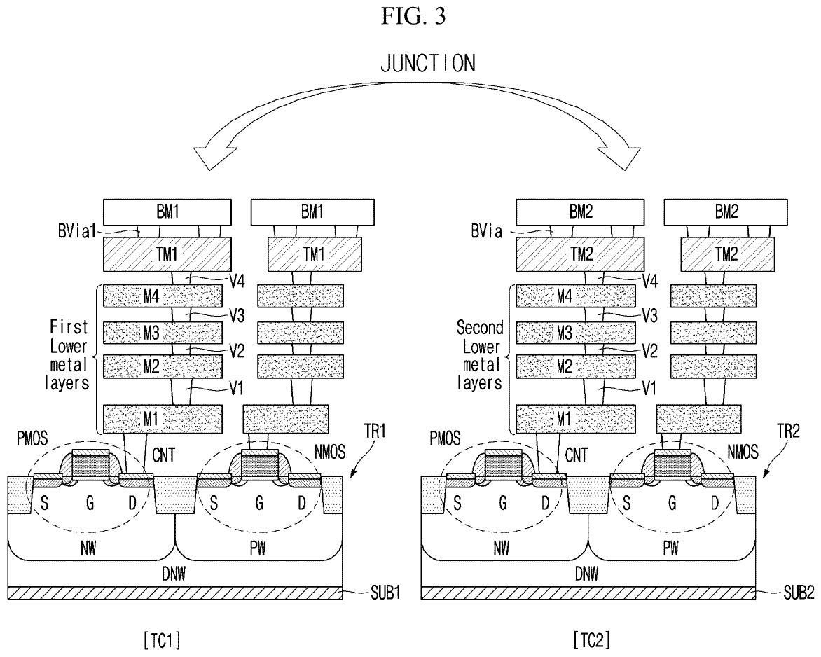

FIG. 3 is a diagram illustrating a first junction example between a first control chip and a second control chip.

Referring to FIG. 3, a first control chip TC1 and a second control chip TC2 may be bonded to each other by bonding metal layers BM1 and BM2 with being flipped.

The first control chip TC1 may include a first transistor element TR1, first lower metal layers M1 to M4 connected to the first transistor element TR1, a first top metal layer TM1 connected to the first lower metal layers M1 to M4, and a first bonding metal layer BM1 connected to the first top metal layer TM1.

The first transistor element TR1 may be implemented with a combination of a PMOS transistor and an NMOS transistor on a first silicone substrate SUB1, but is not limited thereto. The PMOS transistor may be disposed in an N-well (NW) region, and the NMOS transistor may be disposed in a P-well (PW) region. A deep N-well (DNW) region may be disposed between the N-well (NW) region and the first silicone substrate SUB1 and between the P-well (PW) region and the first silicone substrate SUB1.

The first lower metal layers M1 to M4 may be connected to one electrode D of the PMOS transistor and the first top metal layer TM1 through vertical interconnect accesses (referred to as VIAs) V1 to V4 and CNT. Also, the first lower metal layers M1 to M4 may be connected to a gate electrode G of the NMOS transistor and the first top metal layer TM1 through the VIAs V1 to V4 and CNT. The VIAs V1 to V4 and CNT may be implemented with a conductive silicone material passing through insulation layers.

The first top metal layer TM1 and the first bonding metal layer BM1 may be connected to each other through a first bonding VIA BVia1. The first bonding VIA BVia1 may be implemented with a conductive silicone material passing through an insulation layer.

The second control chip TC2 may include a second transistor element TR2, second lower metal layers M1 to M4 connected to the second transistor element TR2, a second top metal layer TM2 connected to the second lower metal layers M1 to M4, and a second bonding metal layer BM2 connected to the second top metal layer TM2.

The second transistor element TR2 may be implemented with a combination of a PMOS transistor and an NMOS transistor on a second silicone substrate SUB, but is not limited thereto. The PMOS transistor may be disposed in an N-well (NW) region, and the NMOS transistor may be disposed in a P-well (PW) region. A deep N-well (DNW) region may be disposed between the N-well (NW) region and the second silicone substrate SUB2 and between the P-well (PW) region and the second silicone substrate SUB2.

The second lower metal layers M1 to M4 may be connected to one electrode D of the PMOS transistor and the second top metal layer TM2 through VIAs V1 to V4 and CNT. Also, the second lower metal layers M1 to M4 may be connected to a gate electrode G of the NMOS transistor and the second top metal layer TM2 through the VIAs V1 to V4 and CNT. The VIAs V1 to V4 and CNT may be implemented with a conductive silicone material passing through insulation layers.

The second top metal layer TM2 and the second bonding metal layer BM2 may be connected to each other through a second bonding VIA BVia2. The second bonding VIA BVia2 may be implemented with a conductive silicone material passing through an insulation layer.

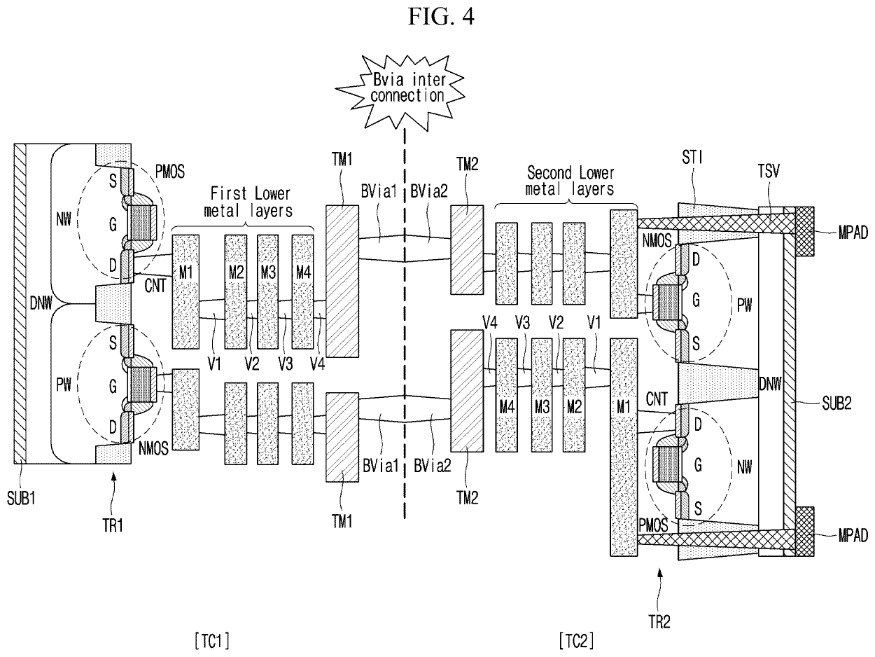

FIG. 4 is a diagram illustrating a second junction example between a first control chip and a second control chip.

Referring to FIG. 4, a first control chip TC1 may include a first transistor element TR1, first lower metal layers M1 to M4 connected to the first transistor element TR1, a first top metal layer TM1 connected to the first lower metal layers M1 to M4, and a first bonding VIA BVia1 connected to the first top metal layer TM1.

A second control chip TC2 may include a second transistor element TR2, second lower metal layers M1 to M4 connected to the second transistor element TR2, a second top metal layer TM2 connected to the second lower metal layers M1 to M4, and a second bonding VIA BVia2 connected to the second top metal layer TM2.

In FIG. 4, configurations of the first and second transistor elements TR1 and TR2 and the first and second lower metal layers M1 to M4 may be replaced with the descriptions of FIG. 3.

Because the first control chip TC1 and the second control chip TC2 are bonded to each other through the first bonding VIA BVia1 and the second bonding VIA BVia2 each including a conductive silicone material, signal distortion and power loss occurring when a signal and power are transferred and received between chips at a high speed may be reduced.

In a junction configuration of FIG. 4, a bonding metal layer may be skipped unlike a junction configuration of FIG. 3, and thus, the cost of materials may be easily reduced. In the junction configuration of FIG. 4, the number of wires of a mount package or the number of metal lines of a semiconductor process used for a connection between chips may be reduced, and thus, a chip size and a mount package size may decrease.

Referring further to FIG. 4, a through silicone VIA (TSV) for a signal connection between an external device and one of the first control chip TC1 and the second control chip TC2 may pass through a silicone substrate and may be connected to a mount pad MPAD. The TSV may pass through a shallow trench isolation (STI) region of a corresponding chip.

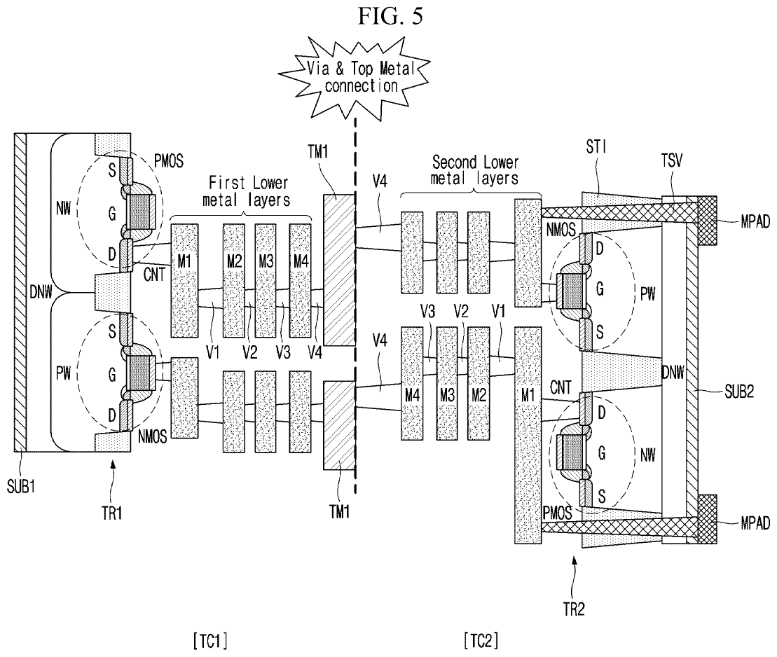

FIG. 5 is a diagram illustrating a third junction example between a first control chip and a second control chip.

Referring to FIG. 5, a first control chip TC1 may include a first transistor element TR1, first lower metal layers M1 to M4 connected to the first transistor element TR1, and a first top metal layer TM1 connected to the first lower metal layers M1 to M4. In FIG. 5, the first bonding VIA BVia1 of FIG. 4 connected to the first top metal layer TM1 may be skipped.

A second control chip TC2 may include a second transistor element TR2, second lower metal layers M1 to M4 connected to the second transistor element TR2, and a VIA V4 connected to the second lower metal layers M1 to M4. In FIG. 5, the second top metal layer TM2 of FIG. 4 connected to the second lower metal layers M1 to M4 and a second bonding VIA BVia2 connected to the second top metal layer TM2 may be skipped.

Because the first control chip TC1 and the second control chip TC2 are bonded to each other through the first top metal layer TM1 and the VIA V4 including a conductive silicone material, signal distortion and power loss occurring when a signal and power are transferred and received between chips at a high speed may be reduced.

In FIG. 5, the first bonding VIA BVia1, the second bonding VIA BVia2, and the second top metal layer TM2 may be further skipped, and thus, a manufacturing process may be simplified, and the manufacturing cost may be reduced.

In FIG. 5, configurations of the first and second transistor elements TR1 and TR2 and the first and second lower metal layers M1 to M4 may be replaced with the descriptions of FIG. 3. Also, a mount pad connection configuration based on a TSV may be replaced with the descriptions of FIG. 4.

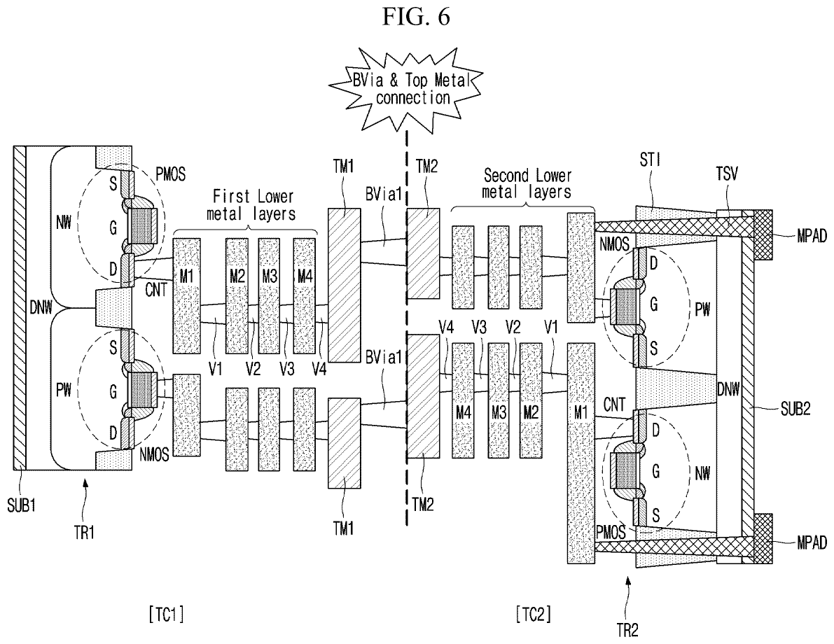

FIG. 6 is a diagram illustrating a fourth junction example between a first control chip and a second control chip.

Referring to FIG. 6, a first control chip TC1 may include a first transistor element TR1, first lower metal layers M1 to M4 connected to the first transistor element TR1, a first top metal layer TM1 connected to the first lower metal layers M1 to M4, and a first bonding VIA BVia1 connected to the first top metal layer TM1.

A second control chip TC2 may include a second transistor element TR2, second lower metal layers M1 to M4 connected to the second transistor element TR2, and a second top metal layer TM2 connected to the second lower metal layers M1 to M4. In FIG. 6, the second bonding VIA BVia2 of FIG. 4 connected to the second top metal layer TM2 may be skipped.

Configurations of the first and second transistor elements TR1 and TR2 and the first and second lower metal layers M1 to M4 may be replaced with the descriptions of FIG. 3.

Because the first control chip TC1 and the second control chip TC2 are bonded to each other through the second top metal layer TM2 and the first bonding VIA BVia1 including a conductive silicone material, signal distortion and power loss occurring when a signal and power are transferred and received between chips at a high speed may be reduced.

In FIG. 6, the second bonding VIA BVia2 of FIG. 4 may be further skipped, and thus, manufacturing process may be simplified, and the manufacturing cost may be reduced.

In FIG. 6, configurations of the first and second transistor elements TR1 and TR2 and the first and second lower metal layers M1 to M4 may be replaced with the descriptions of FIG. 3. Also, a mount pad connection configuration based on a TSV may be replaced with the descriptions of FIG. 4.

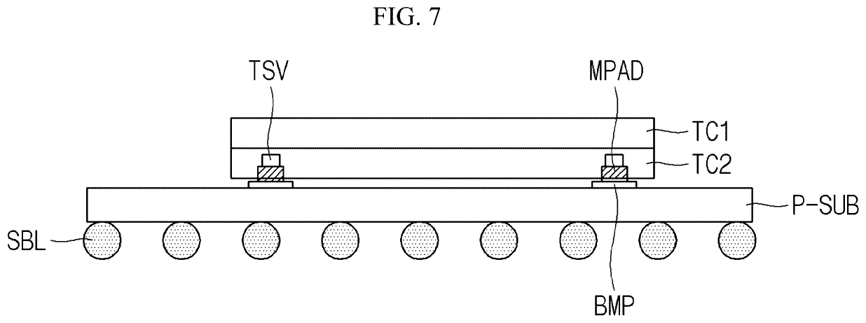

FIG. 7 is a diagram illustrating an example where a stacked timing controller is mounted on a package substrate.

Referring to FIG. 7, a TSV may be formed in a silicone substrate of a second control chip TC2 and may electrically connect one of second lower metal layers to a mount pad MAPD. The TSV may pass through an STI region of the second control chip TC2 and may be connected to the mount pad MPAD. The mount pad MPAD of the second control chip TC2 may be electrically connected to a bumper BMP which is provided on one surface of a package substrate P-SUB.

A solder ball SBL electrically connected to a PCB may be provided on the other surface of the package substrate P-SUB.

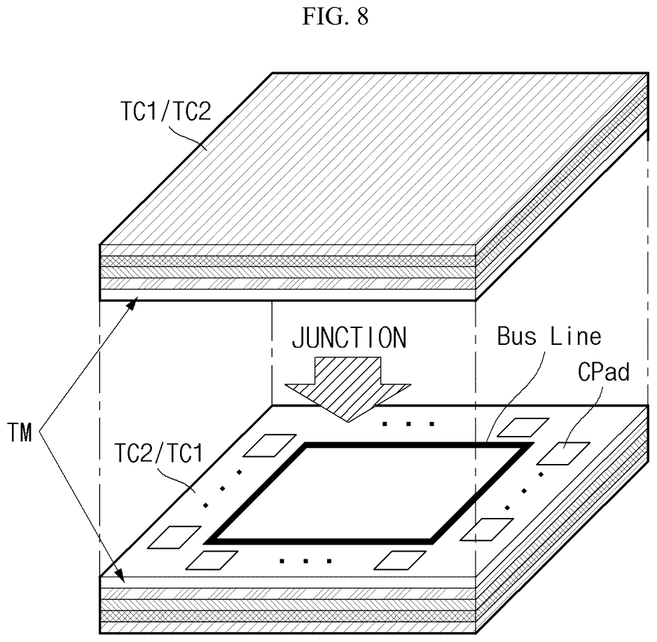

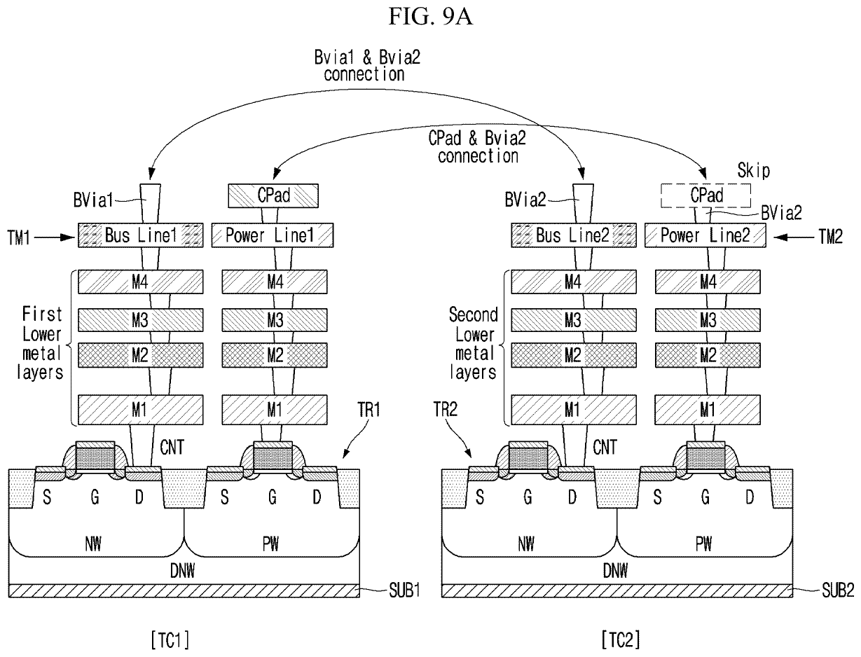

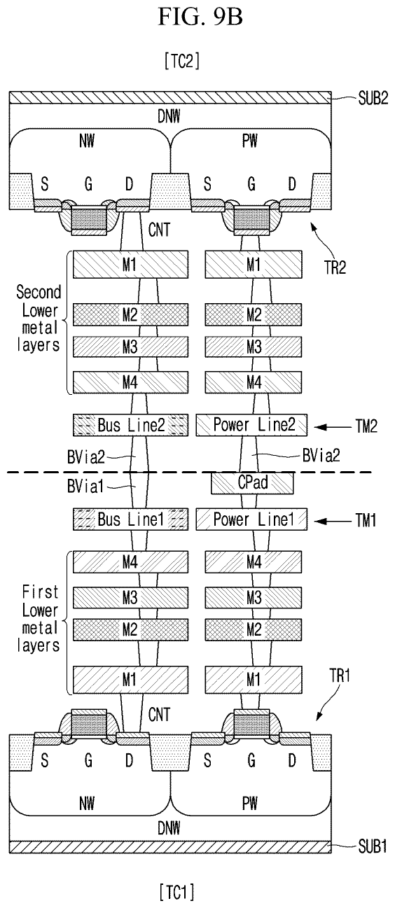

FIG. 8 is a diagram illustrating an example where a bus interface line is formed in a top metal layer included in at least one of a first control chip and a second control chip. FIGS. 9A and 9B are diagrams illustrating a junction example between the first control chip and the second control chip of FIG. 8.

Referring to FIGS. 8, 9A, and 9B, a first bus interface line for signal transfer between first internal elements and a first power line for transferring a driving power to the first internal elements may be formed in a first top metal layer TM1 of a first control chip TC1. A first bonding VIA BVia1 may be connected to the first bus interface line. A bonding pad CPad may be connected to the first power line through the first bonding VIA BVia1. The first internal elements may include a first transistor TR1.

A second bus interface line for signal transfer between second internal elements and a second power line for transferring the driving power to the second internal elements may be formed in a second top metal layer TM2 of a second control chip TC2. A second bonding VIA BVia2 may be connected to the second bus interface line and the second power line. A bonding pad CPad may be skipped in the second control chip TC2.

In a junction configuration between the first control chip TC1 and the second control chip TC2, because the first bonding VIA BVia1 is bonded to the second bonding VIA BVia2 connected to the second bus interface line, and the bonding pad CPad is bonded to the second bonding VIA BVia2 connected to the second power line, signal distortion and power loss occurring when a signal and power are transferred and received between chips at a high speed may be reduced.

Particularly, because the first bus interface line and the first power line are implemented as the same first top metal layer TM1, and the second bus interface line and the second power line are implemented as the same second top metal layer TM2, an additional metal layer for the first and second bus interface lines may be skipped, and thus, a manufacturing process and the manufacturing cost may be reduced.

Because the first control chip TC1 and the second control chip TC2 transfer and receive a signal therebetween through first and second bus interface lines formed in a top metal layer, there may be advantages in terms of signal integrity (SI) and IR drop. The first and second bus interface lines may have a closed loop shape, and thus, there may be an advantage in terms of signal strength.

According to various embodiments of the present disclosure, a connection method between the first control chip TC1 and the second control chip TC2, a direct bonding method and an indirect bonding method based on a VIA may be selectively applied.

For example, in a junction configuration between the first control chip TC1 and the second control chip TC2 illustrated in FIGS. 9A and 9B, at least one of the first bonding VIA BVia1 and the second bonding VIA BVia2 may be skipped. When the first bonding VIA BVia1 is skipped, the first bus interface line may be bonded to the second bonding VIA BVia2, and when the second bonding VIA BVia2 is skipped, the second bus interface line may be bonded to the first bonding VIA BVia1. Also, when all of the first bonding VIA BVia1 and the second bonding VIA BVia2 are skipped, the first bus interface line may be directly bonded to the second bus interface line. Such various connection methods may be applied to the following embodiments.

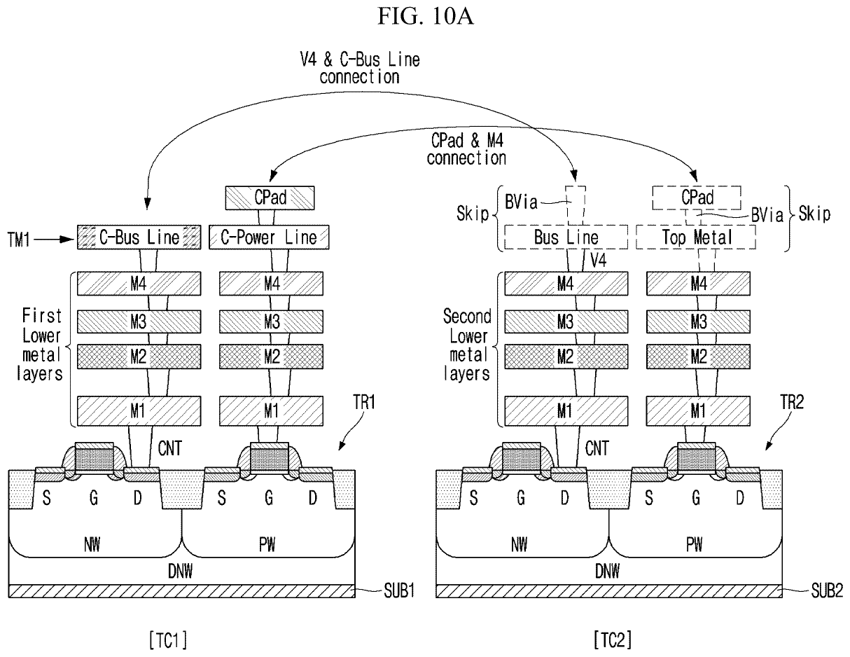

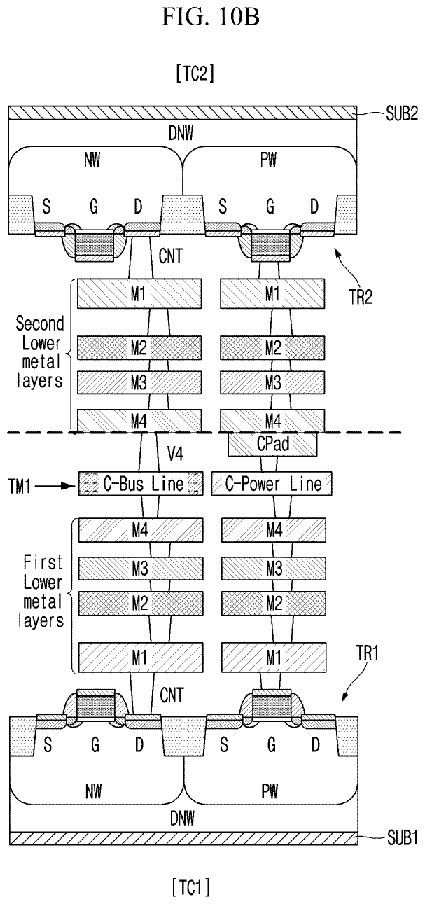

FIGS. 10A and 10B are diagrams illustrating another junction example between the first control chip and the second control chip of FIG. 8.

Referring to FIGS. 8, 10A, and 10B, a common bus interface line (C-BUS Line) for signal transfer between first internal elements and a common power line (C-Power Line) for transferring a driving power to the first internal elements may be formed in a first top metal layer TM1 of a first control chip TC1. A bonding pad CPad may be connected to the common power line (C-Power Line) through a VIA.

A bonding pad CPad, a bonding VIA BVia, and a second top metal layer may be skipped in the first control chip TC1. A VIA V4 may be connected to some M4 of second lower metal layers of a second control chip TC2. The VIA V4 may not be connected to the other M4 of the second lower metal layers of the second control chip TC2.

In a junction configuration between the first control chip TC1 and the second control chip TC2, the common bus interface line (C-BUS Line) may be bonded to the VIA V4, and the bonding pad CPad may be bonded to the other M4 of the second lower metal layers.

The common bus interface line (C-BUS Line) may be used for signal transfer between the first internal elements and the second internal elements, and the common power line (C-Power Line) may transfer the driving power to the first internal elements and the second internal elements. The first internal elements may include a first transistor TR1, and the second internal elements may include a second transistor TR2.

Because the common bus interface line and the common power line are implemented as the same first top metal layer TM1, an additional metal layer for the bus interface lines may be skipped, and thus, a manufacturing process and the manufacturing cost may be reduced.

Because the first control chip TC1 and the second control chip TC2 transfer and receive a signal therebetween through common bus interface lines formed in a first top metal layer, there may be advantages in terms of signal integrity (SI) and IR drop. The common bus interface lines may have a closed loop shape, and thus, there may be an advantage in terms of signal strength.

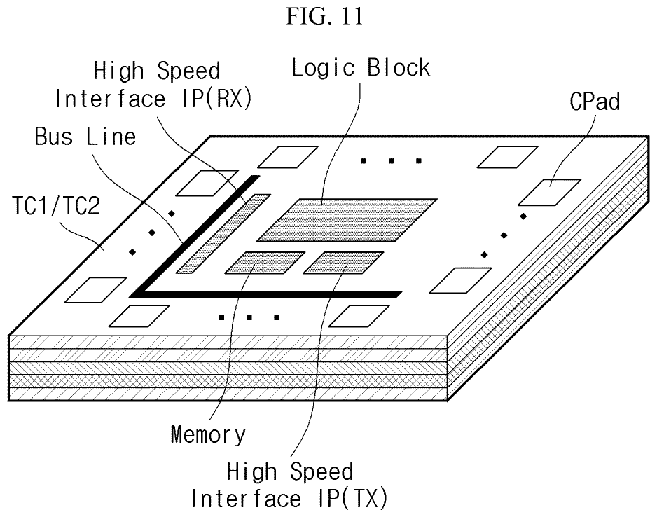

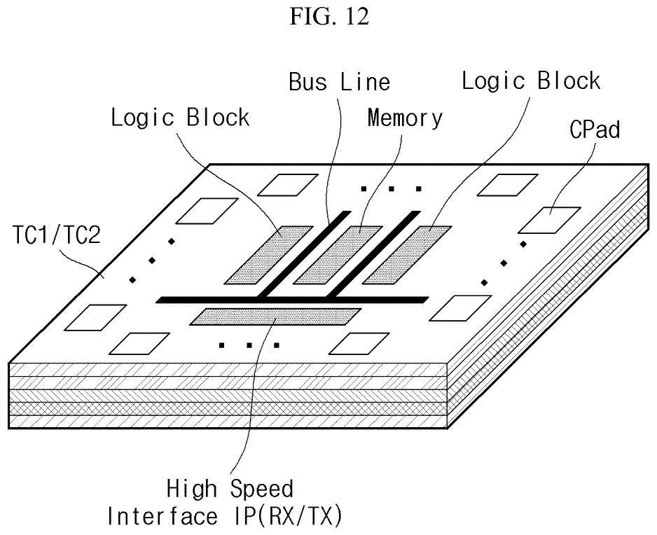

FIGS. 11 and 12 are diagrams illustrating examples where a bus interface line is formed in various open loop shapes in a top metal layer included in at least one of a first control chip and a second control chip.

Referring to FIGS. 11 and 12, a bus interface line for signal transfer between internal elements and a power line for transferring a driving power to the internal elements may be included in a top metal layer included in at least one of a first control chip TC1 and a second control chip TC2. In FIGS. 11 and 12, although a power line is not illustrated, the power line may be formed in another region of the top metal layer where a bus interface line is not formed. In the top metal layer, a thickness of the power line may be greater than that of the bus interface line. Accordingly, loss occurring in a power transfer process may be minimized, and thus, power consumption may be easily reduced.

In FIGS. 11 and 12, the bus interface line may be disposed closer to second internal elements, requiring a second communication speed which is faster than a first communication speed, than first internal elements requiring the first communication speed, and thus, a signal integrity characteristic may be enhanced.

In detail, as in FIG. 11, the bus interface line may be disposed closest to an algorithm logic block, a double data rate (DDR) memory, and high speed interface IPs TX and RX requiring a relatively fast communication speed. In FIG. 11, the bus interface line may be disposed in only a desired region, and thus, may represent an “L” shape. Because the bus interface line is disposed in only a region requiring signal transfer, the use of a space between control chips may increase, and a chip size may be minimized.

Moreover, as in FIG. 12, the bus interface line may be disposed in a “ [symbol] ” shape so that signal transfer between internal elements is easier. Algorithm logic blocks may be arranged in parallel with the DDR memory, where signal interfacing is relatively much performed, therebetween, and moreover, high speed interface IPs TX and RX may be disposed under the DDR memory and the algorithm logic blocks, and the bus interface line may be disposed between two adjacent internal elements of the internal elements. Based on such an arrangement configuration of bus interface lines, organic signal interfacing between the internal elements may be possible, and thus, signal distortion may decrease, and a transfer characteristic may be improved.

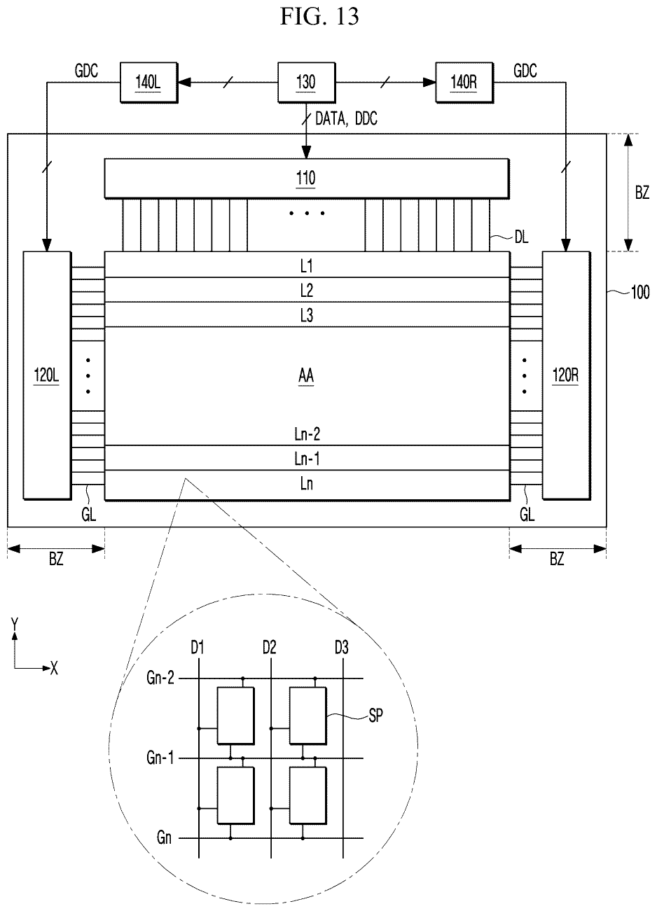

FIG. 13 is a diagram illustrating a display apparatus including a stacked timing controller according to an embodiment of the present disclosure.

Referring to FIG. 13, a display panel according to an embodiment of the present embodiment may be an organic light emitting display apparatus, but is not limited thereto. A display panel 100 may include a screen AA which reproduces an input image. The screen AA may include a pixel array which displays pixel data (hereinafter referred to as “image data”) DATA of an input image. The pixel array may include a plurality of data lines DL, a plurality of gate lines GL intersecting with the data lines DL, and a plurality of pixels SP.

The pixels SP may be arranged on the screen AA in a matrix type defined by intersections between the data lines DL and the gate lines GL. The pixels SP may be arranged as various types such as a stripe type and a diamond type on the screen AA, based on positions of the pixels SP emitting lights of the same color.

The pixel array may include a plurality of pixel columns and a plurality of pixel lines L1 to Ln intersecting with the pixel columns. Each of the pixel columns may include pixels SP which are arranged in a Y-axis direction. A pixel line may include pixels SP which are arranged in an X-axis direction. One vertical period may be one frame period needed for writing image data DATA of one frame in all pixels of the screen. One horizontal period may be a time obtained by dividing one frame period by the number of pixel lines L1 to Ln. One horizontal period may be a time needed for writing the image data DATA of one pixel line, sharing a gate line GL, in pixels SP of one pixel line.

Each of the pixels SP may include a red (R) subpixel, a green (G) subpixel, and a blue (B) subpixel for various color combinations. Each of the pixels SP may further include a white (W) subpixel.

Each of the pixels SP may be implemented with a pixel circuit connected to a data line DL and a gate line GL. The pixel circuit may include a light emitting device, a driving transistor, one or more switch transistors, and a capacitor. The light emitting device may be implemented as an organic light emitting diode (OLED). A driving current applied to the light emitting device may be controlled based on a gate-source voltage of the driving transistor. The gate-source voltage of the driving transistor may be determined by a data voltage corresponding to the image data DATA. In FIG. 1, “D1 to D3” illustrated in a circle may be data lines, and “Gn-2 to Gn” may be gate lines. Each of the pixels SP of FIG. 1 may be further connected to a front-end gate line as well as a current-end gate line. For example, each of pixels SP disposed in an nth pixel line Ln may be connected to a front-end gate line Gn-1 as well as an nth gate line Gn.

The pixel circuit may sample a threshold voltage of the driving transistor in the middle of a pixel programming operation which is performed in one frame period and may allow a sampled threshold voltage to be reflected in a gate-source voltage (hereinafter referred to as Vgs) of the driving transistor, and thus, may prevent a driving current from being distorted due to a threshold voltage variation of the driving transistor.

Semiconductor layers of some transistors configuring the pixel circuit may include low-temperature polycrystalline silicone (hereinafter referred to as LTPS), and semiconductor layers of the other transistors configuring the pixel circuit include oxide.

Touch sensors may be disposed on the display panel 100. The touch sensors may be arranged as an on-cell or add-on type on the screen AA of the display panel 100, or may be implemented as in-cell type touch sensors embedded in the pixel array. A touch input may be sensed through only the pixels SP even without the touch sensors, and in this case, the touch sensors may be skipped.

A display panel driver may include a source driver 110 and gate drivers 120L and 120R. The display panel driver may write the image data DATA in the pixels SP of the display panel 100, based on control by a timing controller 130.

A source driver 110 may convert the image data DATA, received from the timing controller 130, into gamma compensation voltages by using a digital-to-analog converter (DAC) to generate data voltages. The source driver 110 may supply the data voltages to the data lines DL. The data voltages may be supplied to the data lines DL and may be applied to gate electrodes of the driving transistors through the switch transistors of the pixels SP. The source driver 110 may be implemented with a plurality of source drive integrated circuits (ICs).

The gate drivers 120L and 120R may be provided in a bezel region BZ which is outside the screen and does not display an image on the display panel 100. The gate drivers 120L and 120R may sequentially supply a gate signal to the gate lines GL, based on control by the timing controller 130. The gate signal may select pixel lines L1 to Ln where data voltages are charged and may simultaneously activate pixels SP disposed in the pixel lines L1 to Ln. The gate drivers 120L and 120R may output the gate signal by using a plurality of stages and may shift the gate signal. The gate signal may swing between an on level and an off level.

The timing controller 130 may receive video data DATA and a timing signal, synchronized with the video data DATA, from a host system (not shown). The timing signal may include a vertical synchronization signal Vsync, a horizontal synchronization signal Hsync, a clock signal DCLK, and a data enable signal DE. The vertical synchronization signal Vsync may define a vertical period. The horizontal synchronization signal Hsync may define a horizontal period. The data enable signal DE may define a time where the video data DATA is transferred, in a vertical period or a horizontal period. The vertical period and the horizontal period may be determined by a method of counting the data enable signal DE, and thus, the vertical synchronization signal Vsync and the horizontal synchronization signal Hsync may be skipped.

The timing controller 130 may generate a source timing control signal DDC for controlling an operation timing of the source driver 110 and a gate timing control signal GDC for controlling an operation timing of the gate drivers 120L and 120R, based on the timing signal Vsync, Hsync, and DE received from the host system.

The timing controller 130, as described above with reference to FIGS. 1 to 12, may be implemented as a stack type where a first control chip and a second control chip are vertically bonded to each other.

The host system may be one of a television (TV), a set-top box, a navigation system, a personal computer (PC), a home theater, an automotive display system, a mobile device, and a wearable device. In the mobile device and the wearable device, the source driver 110, the timing controller 130, and level shifters 140L and 140R may be integrated into one drive IC.

To reduce an RC delay deviation occurring in the display panel 100 including a large screen, the gate drivers 120L and 120R may be implemented as a double bank type, and thus, gate signals having the same phase may be supplied from both sides of the display panel 100 to the same gate line GL. The gate drivers 120L and 120R may include a first-side gate driver 120L which is disposed in a left bezel region BZ of the display panel 100 and a second-side gate driver 120R which is disposed in a right bezel region BZ of the display panel 100.

The level shifters 140L and 140R may convert a voltage of the gate timing control signal GDC, output from the timing controller 130, into an on-level voltage and an off-level voltage and may supply the on-level voltage and the off-level voltage to the gate drivers 120L and 120R.

The level shifters 140L and 140R may include a first level shifter 140L which is connected to the first-side gate driver 120L through first signal lines and a second level shifter 140R which is connected to the second-side gate driver 120R through second signal lines.

In an example, a first logic circuit of a first design modification period may be designed during the first design modification period. In an example, a first logic circuit of a first design modification period may be made during the first design modification period. In an example, a second logic circuit of a second design modification period may be designed during the second design modification period. In an example, a second logic circuit of a second design modification period may be made during the second design modification period.

In an example, IP may include an implementation. An implementation may include one or more implementations. In an example, hardware IP may include a hardware implementation. A hardware implementation may include hardware circuits. Hardware circuits may include analog circuits and a memory. A circuit may refer to or include a circuit block or a circuit implementation. A memory may refer to or include a memory block or a memory implementation. In an example, software IP may include a software implementation. A software implementation may include instructions executable by a processor. A software implementation may include a processor implementation. A software implementation may include a processor and a memory, where the memory stores instructions executable by the processor.

The present disclosure may realize the following effects.

The stacked timing controller according to the embodiments of the present disclosure may be configured based on a vertical junction between a first control chip and a second control chip, which are designed based on dualization. Circuit blocks substantially requiring no design modification may be designed in the first control chip which is high in cost, and circuit blocks where design modification is frequently performed may be designed in the second control chip which is low in cost, and thus, time and cost needed for upgrading may be considerably reduced.

In the stacked timing controller according to the embodiments of the present disclosure at least one of the first control chip and the second control chip may include a bus interface line which is formed in an empty space of a top metal layer used as a power line, thereby decreasing the manufacturing cost.

In the stacked timing controller according to the embodiments of the present disclosure the bus interface line may be disposed closer to second internal elements, requiring a second communication speed which is faster than a first communication speed, than first internal elements requiring the first communication speed, and thus, a signal integrity characteristic may be enhanced. Also, because the bus interface line is disposed in only a region requiring signal transfer, the use of a space between control chips may increase, and a chip size may be minimized.

The effects according to the present disclosure are not limited to the above examples, and other various effects may be included in the specification.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

What is claimed is:

1. A stacked timing controller, comprising:
a first control chip manufactured by a wafer process of a first circuit line width; and
a second control chip manufactured by a wafer process of a second circuit line width,
wherein the second circuit line width is greater than the first circuit line width,
wherein the second control chip is vertically bonded to the first control chip,
wherein the first control chip comprises at least one first logic circuit of a first design modification period, and
wherein the second control chip comprises at least one second logic circuit of a second design modification period which is shorter than the first design modification period.

2. The stacked timing controller of claim 1, wherein the first control chip further comprises a hardware implementation including analog circuits and a memory, and
the second control chip further comprises a software implementation.

3. The stacked timing controller of claim 1, wherein the first control chip and the second control chip have a same size.

4. The stacked timing controller of claim 1, wherein the first control chip comprises a first transistor element, first lower metal layers connected to the first transistor element, a first top metal layer connected to the first lower metal layers, and a first bonding metal layer connected to the first top metal layer,
the second control chip comprises a second transistor element, second lower metal layers connected to the second transistor element, a second top metal layer connected to the second lower metal layers, and a second bonding metal layer connected to the second top metal layer, and
the first bonding metal layer and the second bonding metal layer are bonded facing each other.

5. The stacked timing controller of claim 1, wherein the first control chip comprises a first transistor element, first lower metal layers connected to the first transistor element, a first top metal layer connected to the first lower metal layers, and a first bonding vertical interconnect access (VIA) connected to the first top metal layer,
the second control chip comprises a second transistor element, second lower metal layers connected to the second transistor element, a second top metal layer connected to the second lower metal layers, and a second bonding VIA connected to the second top metal layer, and
the first bonding VIA and the second bonding VIA are bonded facing each other.

6. The stacked timing controller of claim 1, wherein the first control chip comprises a first transistor element, first lower metal layers connected to the first transistor element, and a first top metal layer connected to the first lower metal layers, and
the second control chip comprises a second transistor element, second lower metal layers connected to the second transistor element, and a vertical interconnect access (VIA) connected to the second lower metal layers, and
the first top metal layer and the VIA are bonded facing each other.

7. The stacked timing controller of claim 1, wherein the first control chip comprises a first transistor element, first lower metal layers connected to the first transistor element, a first top metal layer connected to the first lower metal layers, and a first bonding vertical interconnect access (VIA) connected to the first top metal layer,
the second control chip comprises a second transistor element, second lower metal layers connected to the second transistor element, and a second top metal layer connected to the second lower metal layers, and
the first bonding VIA and the second top metal layer are bonded facing each other.

8. The stacked timing controller of claim 1, wherein the first control chip comprises a first top metal layer where a first bus interface line for signal transfer between first internal elements and a first power line for transferring a driving power to the first internal elements are formed, a first bonding vertical interconnect access (VIA) connected to the first bus interface line, and a bonding pad connected to the first power line,
the second control chip comprises a second top metal layer, where a second bus interface line for signal transfer between second internal elements and a second power line for transferring a driving power to the second internal elements are formed, and a second bonding VIA connected to each of the second bus interface line and the second power line, and
the first bonding VIA is bonded to the second bonding VIA connected to the second bus interface line, and the bonding pad is bonded to the second bonding VIA connected to the second power line.

9. The stacked timing controller of claim 1, wherein the first control chip comprises a first top metal layer, where a common bus interface line for signal transfer between first internal elements and a common power line for transferring a driving power to the first internal elements are formed, and a bonding pad connected to a first power line,
the second control chip comprises second lower metal layers connected to second internal elements and a vertical interconnect access (VIA) connected to some of the second lower metal layers,
the common bus interface line is bonded to the VIA, and the bonding pad is bonded to one of the second lower metal layers,
the common bus interface line is further configured to be used for signal transfer between the second internal elements, and
the common power line is further configured to transfer a driving power to the second internal elements.

10. The stacked timing controller of claim 8, wherein each of the first bus interface line, the second bus interface line, and a common bus interface line has a closed loop shape.

11. The stacked timing controller of claim 9, wherein each of a first bus interface line, second bus interface line, and the common bus interface line has a closed loop shape.

12. The stacked timing controller of claim 1, wherein a bus interface line for signal transfer between internal elements and a power line for transferring a driving power to the internal elements are included in a top metal layer included in at least one of the first control chip and the second control chip, and
the bus interface line is disposed closer to second internal elements than first internal elements, and the second internal elements require a second communication speed which is faster than a first communication speed required by the first internal elements.

13. The stacked timing controller of claim 12, wherein the bus interface line has an “L” shape or a “ [symbol] ” shape.

14. A stacked timing controller, comprising:
a first control chip manufactured by a wafer process of a first circuit line width; and
a second control chip manufactured by a wafer process of a second circuit line width,
wherein the second circuit line width is greater than the first circuit line width,
wherein the second control chip is vertically bonded to the first control chip, and
wherein a bus interface line for signal transfer between internal elements and a power line for transferring a driving power to the internal elements are included in a top metal layer included in at least one of the first control chip and the second control chip.

15. The stacked timing controller of claim 14, wherein the bus interface line is disposed closer to second internal elements than first internal elements, and the second internal elements require a second communication speed which is faster than a first communication speed required by the first internal elements.

16. A display apparatus, comprising:
a display panel where pixels and pixel driving lines are disposed;
a panel driver configured to drive the pixel driving lines; and
the stacked timing controller of claim 1 configured to control an operation of the panel driver.
